(19) United States
(12) Patent Application Publication
(10) Pub. No.: US 2010/0274404 A1
(43) Pub. Date: Oct. 28, 2010

(54) PROCESS AND METHODOLOGY TO COLLECT, ANALYZE, AND SIGNAL REAL-TIME ELECTRON SOURCES OF AN ELECTRICAL GRID

(75) Inventor: James D. Holbery, Kirkland, WA (US)

Correspondence Address: SCHWABE, WILLIAMSON & WYATT, P.C., 1420 FIFTH, SUITE 3400, SEATTLE, WA, 98101-4010, US

(73) Assignee: GRID MOBILITY LLC, Kirkland, WA (US)

(21) Appl. No.: 12/769,561

(22) Filed: Apr. 28, 2010

Related U.S. Application Data
(60) Provisional application No. 61/173,490, filed on Apr. 28, 2009.

(51) Int. Cl. G06F 1/28; G01R 21/00; G06F 19/00

(52) U.S. Cl. 700/291; 702/62

(57) ABSTRACT

Embodiments of methods and apparatuses for collecting, analyzing, and transmitting real-time electron sources of an electrical grid are disclosed herein. In various embodiments, a computing device may be configured to collect data describing present generating source or sources for one or more present supplies of electricity to an electrical grid. Additionally, the computing device may be configured to analyze the data, and determine an amount of a present electricity flow on the electrical grid being generated from one or more renewable sources. Further, the computing device may be configured to generate and transmit a signal or message to one or more devices associated with consumption and/or storage of electricity supplied by the electrical grid, based at least in part on the result of said analysis and determination. Other embodiments may be described and claimed.

### RELATED APPLICATIONS

The present application is a non-provisional application of, and claims priority to the U.S. Provisional Application 61/173,490, entitled “PROCESS AND METHODOLOGY TO AGGREGATE, ANALYZE, AND TRANSMIT REAL-TIME ELECTRON SOURCES WITHIN THE ELECTRICAL GRID,” filed Apr. 28, 2009. The specification of the provisional application is hereby incorporated by reference, to the extent they are consistent with the present specification.

### TECHNICAL FIELD

Embodiments of the present disclosure relate to the field of electricity generation, distribution and consumption, more specifically, to methods and apparatuses for collecting, analyzing, and signaling real-time electron sources of an electrical grid.

### BACKGROUND

With increased concern over climate change, cost of fossil fuels, and so forth, there is an increase in interest in switching to use electricity for energy, e.g., the increased popularity of electric or hybrid vehicles. Also, there is an increased interest in generating and consuming more electricity generated from renewable sources, such as, wind, solar, hydro, bio mass, geothermal, and nuclear (which for the purpose of this application, are all considered “renewable sources”). The switching, as well as generating/storing/consuming more electricity from renewable sources have been relatively slow, because in part the lack of mechanisms for consumers to be informed of the generation or electron sources.

### SUMMARY OF INVENTION

Embodiments of methods and apparatuses for collecting, analyzing, and signaling real-time electron sources of an electrical grid are disclosed herein. In various embodiments, a computing device may be configured to collect data describing present generating source or sources for one or more present supplies of electricity to an electrical grid. Additionally, the computing device may be configured to analyze the data, and determine an amount of a present electricity flow on the electrical grid being generated from one or more renewable sources. Further, the computing device may be configured to generate and transmit a signal or a message to one or more devices associated with consumption or storage of electricity supplied by the electrical grid, based at least in part on the result of said analysis and determination.

In various embodiments, the collecting operation may include collecting from one or more electricity generating entities presently generating and supplying electricity to the electrical grid. In various embodiments, the analysis operation may include aggregating the collected data, and determining a percentage of the present electricity flow on the electrical grid being generated from renewable source or sources. In various embodiments, the analysis operation may include determining whether the amount of the present electricity flow on the electrical grid being generated from one or more renewable sources is less than a current electricity consumption load above a base line level of generation of the electrical grid. In various embodiments, the computing device may be configured to forecast whether the amount of the present electricity flow on the electrical grid being generated from one or more renewable sources, in an upcoming time period, will be greater than an expected electricity consumption load above a base line level of generation of the electrical grid.

In various embodiments, the generating and transmitting operations may be performed in response to determining the percentage of the present electricity flow on the electrical grid being generated from renewable source or sources, determining the amount of the present electricity flow on the electrical grid being generated from one or more renewable sources is less than a current electricity consumption load above a base line level of generation of the electrical grid, or forecasting the amount of the present electricity flow on the electrical grid being generated from one or more renewable sources, in an upcoming time period, will be greater than an expected electricity consumption load above a base line level of generation of the electrical grid.

### BRIEF DESCRIPTION OF THE DRAWINGS

Embodiments of the present disclosure will be described by way of exemplary embodiments, but not limitations, illustrated in the accompanying drawings in which like references denote similar elements, and in which:

FIG. 1 illustrates a network overview of the apparatuses of the present disclosure, in accordance with various embodiments;

FIG. 2 illustrates an operational overview of the methods of the present disclosure, in accordance with various embodiments;

FIG. 3 illustrates example profiles of electricity demand, base line generation, and generation from a renewable source for an electrical grid, in accordance with various embodiments;

FIG. 4 illustrates an example of electrical consumption load shifting, in accordance with various embodiments;

FIG. 5 illustrates an example controller and outlet arrangement, suitable for use to practice aspects of the present disclosure, in accordance with various embodiments; and

FIG. 6 illustrates an example computer system, suitable for use to practice aspects of the present disclosure, in accordance with various embodiments.

### DETAILED DESCRIPTION OF ILLUSTRATIVE EMBODIMENTS

Illustrative embodiments of the present disclosure include but are not limited to methods and apparatuses for collecting, analyzing, and signaling real-time electron sources of an electrical grid. Various aspects of the illustrative embodiments will be described using terms commonly employed by those skilled in the art to convey the substance of their work to others skilled in the art. However, it will be apparent to those skilled in the art that alternate embodiments may be practiced with only some of the described aspects. For purposes of explanation, specific numbers, materials, and configurations are set forth in order to provide a thorough understanding of the illustrative embodiments. However, it will be apparent to one skilled in the art that alternate embodiments may be practiced without the specific details. In other instances, well-known features are omitted or simplified in order not to obscure the illustrative embodiments.

Further, various operations will be described as multiple discrete operations, in turn, in a manner that is most helpful in understanding the illustrative embodiments; however, the order of description should not be construed as to imply that these operations are necessarily order dependent. In particular, these operations need not be performed in the order of presentation.

The phrase “in one embodiment” is used repeatedly. The phrase generally does not refer to the same embodiment; however, it may. The terms “comprising,” “having,” and “including” are synonymous, unless the context dictates otherwise. The phrase “A/B” means “A or B.” The phrase “A and/or B” means “(A), (B), or (A and B).” The phrase “at least one of A, B, and C” means “(A), (B), (C), (A and B), (A and C), (B and C) or (A, B and C).” The phrase “(A) B” means “(B) or (A B)”, that is, A is optional.

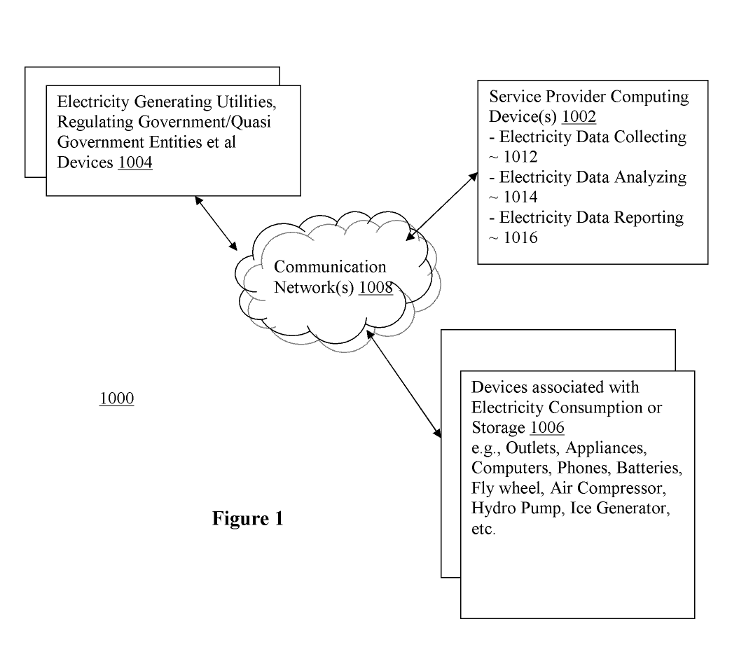

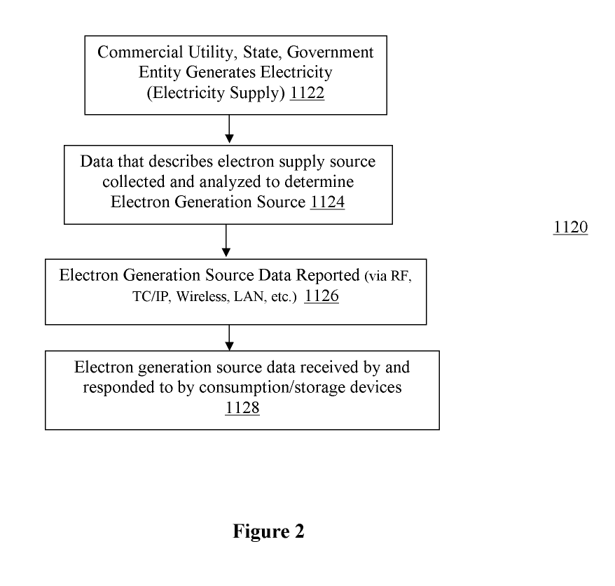

FIG. 1 illustrates a network overview of the apparatuses of the present disclosure, in accordance with various embodiments. As illustrated, computing device or devices 1002 of a Service Provider, incorporated with the teachings of the present disclosure, devices 1004 of electricity generating utilities, regulating government/quasi-government entities, and devices 1006 associated with electricity consumption, may be coupled to each other via one or more communication networks 1008. In various embodiments, computing device or devices (hereinafter simply “device”) 1002 may be configured with Electricity Data Collecting (EDC) function 1012, Electricity Data Analyzing (EDA) function 1014, and Electricity Data Reporting (EDR) function 1016, to be described more fully below, in particular with references to FIGS. 2-4 and 6.

Devices 1004 are intended to represent a broad range of devices capable of communicating electricity generation data for an electrical grid, for collection by device 1002. Utilities, government/quasi-government entities are intended to represent a broad range of such entities associated with the generation and distribution of electricity for consumption by residential, commercial and/or industrial users/entities.

Similarly, devices 1006 are intended to represent a broad range of devices associated with electricity consumption or storage, including outlets, appliances, batteries, fly wheel, air compressor, hydro pump, ice generator, and so forth, as well as communication devices associated with electricity consumers or storing entities.

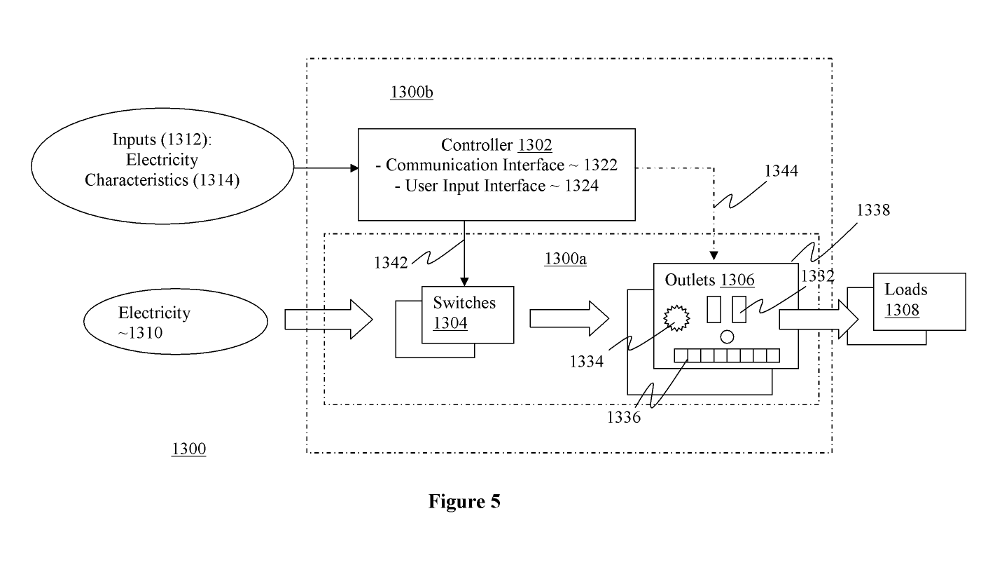

Examples of various outlets particularly suitable for practicing various aspects of the present disclosure will described later with references to FIG. 5. Example of communication devices associated with electricity consumers may include, but are not limited to, computers, mobile phones, and the like.

Communication networks 1008 may include one or more public and/or private communication networks, including but are not limited to the Internet, Broadband and/or Cellular communication offered by communication carriers, and/or private enterprise networks.

Before proceeding to further describe the present disclosure, it should be noted, while for ease of understanding, the operations of data collecting, analyzing and signaling are shown to be performed by devices 1002 of a service provider, separate from the electricity generating entities or government/quasi government regulatory bodies, it is anticipated that in embodiments, some of all of the collecting, analyzing and signaling functions may be endowed and performed by one or more of the generating entities or government/quasi government regulatory bodies instead. Further, while the present disclosure is being described in terms of embodiments signaling real time renewable source or sources, the information may be conveyed to electricity consumer, storage entities, and other parties of interest in other manner, e.g., but not limited to messaging of various types, such as Short Messaging Service (SMS). The embodiments are selected for illustration for ease of understanding, and are not to be construed as limiting on the scope of the present disclosure.

Referring now also to FIG. 2, wherein an overview of various methods of the present disclosure, in accordance with various embodiments, is shown. As illustrated, in various embodiments, a method of the present disclosure may start in block 1122, with commercial utilities, governmental and/or quasi government entities generating electricity for an electrical grid. The electricity may be generated using conventional fossil fuel, such as coal, in combination with one or more renewable sources, such as wind, solar, hydro, geothermal, bio mass, and nuclear (which for the purpose of the present application, are all considered as renewable sources).

From block 1122, embodiments of the method may proceed to block 1124, where data describing electricity generation sources may be collected, e.g. by EDC function 1012, and analyzed, e.g. by EDA function 1014, both of devices 1002. In various embodiments, collection and analysis may both be real time or periodic, or with collection continuous and analysis periodic (with the collected data being stored and accumulated). Upon collection and analysis, block 1124, embodiments of the method may proceed to block 1126, where the results of the analysis may be reported to devices 1006 associated with consuming or storing electricity supplied by the electrical grid, e.g. by EDR 1016 of devices 1002. In various embodiments, reporting may be made via a signal or a message. On receipt of the reports, in block 1128, electricity consumption or storage of the devices 1006 or associated with devices 1006, may adjust their electricity consumption responsively to the reports received. In various embodiments, incentives may be provided by the utilities and/or governmental/quasi-governmental entities to induce the consumers or the storing entities to respond and adjust their consumption or storage behaviors in view of generation source reporting provided. From the perspective of the electricity generating entities, an entity drawing electricity off the grid and storing the electricity for subsequent consumption may be, for all practical purpose, considered consuming electricity. Thus, unless the distinction is necessary, the terms “consuming” and “storing” may be considered synonymous.

In various embodiments, in block 1124, EDA function 1014 of device 1002 may aggregate the collected data, and determine a percentage of the present electricity flow on the electrical grid being generated from renewable source or sources. For these embodiments, in block 1126, EDR function 1016 of device 1002 may, in response, generate and transmit a signal to devices 1006 to convey, solely or among other things, the percentage of the present electricity flow on the electrical grid being generated from renewable source or sources. In block 1128, devices 1006 or consumption/storage devices associated with the report receiving devices 1006 may adjust and modify their electric consumption/storage behavior, in view of the reported percentage of electricity generated from renewable sources.

In various embodiments, in block 1124, EDA function 1014 of device 1002 may determine whether the amount of the present electricity flow on the electrical grid being generated from one or more renewable sources is less than a current electricity consumption load (hereinafter, simply “load”) above a base line level of generation of the electrical grid. For these embodiments, in block 1126, EDR function 1016 of device 1002 may, in response, generate and transmit a signal, for a time period, conveying a signal discouraging present consumption of electricity, thereby potentially shifting a portion of the otherwise current load to after the time period, where presumably more electricity generated from renewable sources will be available.

In various embodiments, in block 1124, EDA function 1014 of device 1002 may forecast whether the amount of the present electricity flow on the electrical grid being generated from one or more renewable sources, in an upcoming time period, will be greater than an expected electricity consumption load above a base line level of generation of the electrical grid. For these embodiments, in block 1126, EDR function 1016 of device 1002 may, in response, generates and transmits a signal, for a time period, conveying a signal discouraging present consumption of electricity, thereby similarly potentially shifting a portion of the otherwise current load to after the time period, where presumably more electricity generated from renewable sources will be available.

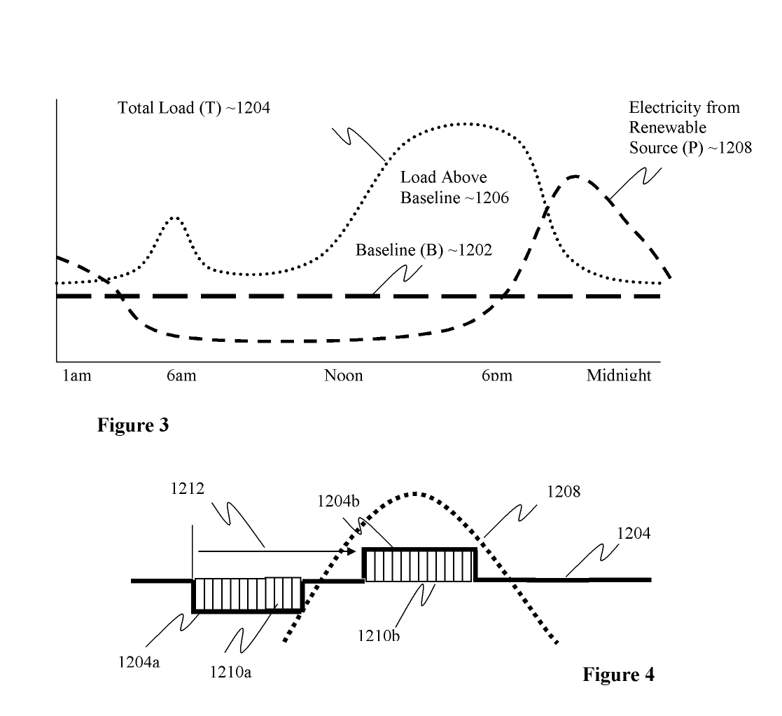

FIG. 3 illustrates example profiles of electricity demand, base line generation, and generation from an intermittent renewable source for an electrical grid, in accordance with various embodiments. Dashed line 1202 may represent an example base line electricity generation (B) of various electricity generating entities associated with an electrical grid, over a 24-hr period. Dotted line 1204 may represent an example total consumption load (T) over the same time period. The area 1206 between dotted line 1204 and dashed line 1202 may be referred to as “load above baseline” (LAB). Dashed line 1208 represent an example electricity generation of an intermittent renewable source, in this case, from wind energy, as wind tends to pick up and produce more electricity in the late evening period. While not explicitly illustrated, electricity generation from solar energy would increase during daytime instead, a different complementary period to wind generated electricity.

FIG. 4 illustrates an example of electrical consumption load shifting, in accordance with various embodiments. Thus, by generating and transmitting a signal 1212, based either on determining that currently P<LAB, or forecasting in a future period that P>LAB, and providing a signal to discourage electricity consumption (coupled with incentives offered by the electricity generating entities and/or government/quasi government regulatory bodies) as described earlier, a portion of the otherwise current load 1210a may be shifted to become consumption load 1210b while more electricity are generated from a renewable source, as depicted by the dotted line 1208. Accordingly, electricity consumers may be provided with the guidance (and incentives) to contribute to temporarily lowering the total load 1204 to level 1204a when less electricity is generated from a renewable source, and increased to level 1204b when more electricity is generated from a renewable source.

However, electricity consumers/storing entities may not respond to the signaling and incentives, changing their consumption/storage behaviors in response to change in the availability of electricity from renewable source(s) in the ideal manner as the generating utilities would like. Thus, in various embodiments, data collecting and analyzing functions 1012 and 1014 may also be configured to gather and analyze consumer and storing entities responsive behaviors, and adapt the timing of the signaling operations and incentives to induce the desired shift in consumption/storage. In various embodiments, data collecting and analyzing functions 1012 and 1014 may be configured to determine the rate of change in consumption/storage (δP/δt), and the point or points of inflection (δ²P/δτ²⁾) of the consumer/storing entities' response curve. In various embodiments, signaling may be performed at or near the point or points of inflection.

Thus, unlike the prior art, where electricity generation is responsive or follow change in demand, under the present disclosure, electricity generation may potentially lead the change in demand.

As described earlier, the signal conveying a current percentage of electricity being generated from one or more renewable sources, or a signal to discourage or encourage consumption or storage of electricity, may be transmitted to a power consumption/storage device 1006, such as an outlet, an appliance, a flywheel, and so forth, or a communication device associated with a consumer or storage entity of electricity. FIG. 5 illustrates an example outlet arrangement, suitable for receiving the signal, and in response, adjusting the availability of electricity through outlet, thereby affecting the consumption of electricity by load electrically coupled to the outlet, in accordance with various embodiments. The outlet arrangement 1300 and a system formed with multiple ones of the arrangement and a remote control server, are the subjects of a co-pending application, number (to be assigned), entitled “Outlet Arrangement and System,” contemporaneously filed (attorney docket reference: 120814-175549).

As shown, in various embodiments, electrical outlet arrangement 1300 may include one or more electrical outlets 1306 and one or more switches 1304 coupled with each other. Each electrical outlet 1306 may be provided to accept electrical coupling from a corresponding load 1308, to consume electricity flow provided to the electrical outlet when electricity flow 1310 to the electrical outlet is enabled. The one or more electrical outlets 1306 may be electrically coupled with one or more switches 1304 configured to enable or disenable electricity flow 1310 to the one or more electrical outlets 1306, in response to the control of controller 1302. In various embodiments, arrangement 1300 may further include local controller 1302. In various embodiments, local controller 1302 may be communicatively coupled 1342 with the one or more switches 1304, and configured to control the one or more switches 1304 to enable or disable electricity flow 1310 in response to an input 1312, e.g., a characterization value 1314 of the electricity flow 1310, provided to controller 1302 by a user and/or a remote control server (not shown). In various embodiments, a remote control server (not shown) may control multiple arrangements 1300 located in dispersed locations.

In various embodiments, the characterization value, as described earlier, may denote a percentage of the electricity flow 1310 being generated using one or more renewable sources or an encouragement/discouragement to consume electricity.

In various embodiments, each electrical outlet 1306 may include a socket 1332 configured to accept electrical coupling from a corresponding load 1308 for consumption of electricity flow provided to the electrical outlet, when provision of electricity flow is enabled. Additionally, in various embodiments, each or a group of electrical outlets 1306 may be provided with a display 1336, e.g., an array of multi-color LED, including green LED, to display the percentage of the electricity flow being generated using one or more renewable sources or black LED, to display the percentage of the electricity flow being generated using fossil fuel, or both. Further, each or a group of electrical outlets 1306 may be provided with a visual indicator 1334, e.g., a green or red light emitting device (LED), configured to provide visual indication to a user that consumption of electricity flow 1310 through the electrical outlet(s) 106 is being discouraged or encouraged.

In various embodiments, visual indicator 1334 and display 1336 may be disposed on an exterior surface of a housing 1338 configured to house one or more of electrical outlets 1306. In various embodiments, each or a group of outlets 1306 may include a communication interface (not shown) coupling visual indicator 1334 and display 1336 to controller 1302, enabling controller 1302 to control visual indicator 1334 and display 1336. Communication interface may be configured for wired or wireless communication with controller 1302.

In various embodiments, communication interface 1322 may include, but are not limited to, wired, such as Ethernet, or wireless, WiFi, Wireless Metropolitan (WiMax), Enhanced Data GMS Environment (EDGE), 3^{rd} generation broadband (3G), 4^{th} generation broadband (4G) or the like. Communication with controller 1302 may be in accordance of any one of a number of messaging protocols, including but are not limited, Transmission Control Protocol/Internet Protocol (TCP/IP), Short Messaging Services (SMS), and the like.

In various embodiments, one of loads 1308 or outlets 1306 may be a storage device. In various embodiments, each storage device (battery, air compressor, flywheel, ice generator, etc.) may include a battery bank (or similar apparatus or assembly) configured to store electricity for future deployment when provision of electricity flow is enabled. Additionally, in various embodiments, each group of storage devices may be similarly provided with a display (1336) e.g., an array of multi-color LED, including green LED, to display the percentage of the electricity flow being stored or delivered using one or more renewable sources or black LED, to display the percentage of the electricity flow being generated using fossil fuel, or both. Further, each or a group of electrical storage devices may also be similarly provided with a visual indicator 1334, e.g., a green or red light emitting device (LED), configured to provide visual indication to a user that storage or delivery of electricity flow through the storage device is being discouraged or encouraged.

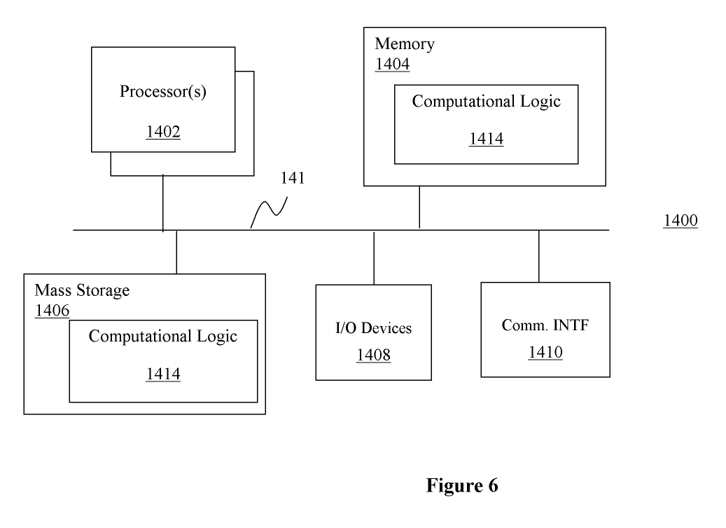

FIG. 6 illustrates an example computer system or computing device, suitable for use to practice aspects of the present disclosure, in particular, devices 1002, in accordance with various embodiments. As shown, exemplary computing system or computing device 1400 includes one or more processors 1402 and system memory 1404. Additionally, system/device 1400 may include mass storage devices 1406 (such as diskette, hard drive, CDROM and so forth), input/output devices 1408 (such as keyboard, cursor control and so forth) and communication interfaces 1410 (such as network interface cards, modems and so forth). The elements may be coupled to each other via system bus 1412, which represents one or more buses. In the case of multiple buses, the buses may be bridged by one or more bus bridges (not shown).

Each of these elements performs its conventional functions known in the art. In particular, system memory 1404 and mass storage 1406 may be employed to store a working copy and a permanent copy of the programming instructions (computing logic 1414) and/or data, implementing the teachings of the present disclosure (e.g., earlier described EDC function 1012, EDA function 1014 and EDR function 1016). The programming instructions may be instructions of any one of a number of known or to be designed languages, including but are not limited to C, C++, Perl, Java, Javascript, XML, HTML and so forth. All or a portion of the permanent copy of the programming instructions/data may be loaded into mass storage 1406 in the factory, in the field (via a distribution medium) or through communication interface 1410 (from a distribution server (not shown)).

The constitution of elements 1402-1412 are known, and accordingly will not be further described.

Although specific embodiments have been illustrated and described herein, it will be appreciated by those of ordinary skill in the art that a wide variety of alternate and/or equivalent implementations may be substituted for the specific embodiments shown and described, without departing from the scope of the present disclosure. This application is intended to cover any adaptations or variations of the embodiments discussed herein. Therefore, it is manifestly intended that this disclosure be limited only by the claims and the equivalents thereof.

What is claimed is:

1. A method comprising:
collecting, by a computing device, data describing present generating source or sources for one or more present supplies of electricity to an electrical grid;
analyzing the data, by the computing device, to determine an amount of a present electricity flow on the electrical grid being generated from one or more renewable sources; and
generating and transmitting, by the computing device, a signal or a message to one or more devices associated with consumption or storage of electricity supplied by the electrical grid, based at least in part on the result of said analysis and determination.

2. The method of claim 1, wherein collecting comprises collecting, by the computing device, from one or more electricity generating entities presently generating and supplying electricity to the electrical grid.

3. The method of claim 1, wherein analyzing comprises aggregating, by the computing device, the collected data, and determining a percentage of the present electricity flow on the electrical grid being generated from renewable source or sources.

4. The method of claim 3, wherein generating and transmitting comprise generating and transmitting a signal or a message, by the computing device, in response to said determining, to convey the percentage to the one or more devices.

5. The method of claim 1, wherein analyzing comprises determining whether the amount of the present electricity flow on the electrical grid being generated from one or more renewable sources is less than a current electricity consumption load above a base line level of generation of the electrical grid.

6. The method of claim 5, wherein generating and transmitting comprise generating and transmitting a signal or message, by the computing device, in response to determining that the amount of the present electricity flow on the electrical grid being generated from one or more renewable sources is less than a current electricity consumption load above a base line level of generation of the electrical grid by a predetermined amount.

7. The method of claim 1, further comprising forecasting, by the computing device, whether the amount of the present electricity flow on the electrical grid being generated from one or more renewable sources, in an upcoming time period, will be greater than an expected electricity consumption load above a base line level of generation of the electrical grid.

8. The method of claim 7, wherein generating and transmitting comprise generating and transmitting a signal or message, by the computing device, in response to determining that the amount of the present electricity flow on the electrical grid being generated from one or more renewable sources, in an upcoming time period, will be greater than a current electricity consumption load above a base line level of generation of the electrical grid.

9. The method of claim 1, wherein transmitting comprising transmitting a signal to a controller associated with an electrical outlet, by the computing device.

10. The method of claim 1, wherein transmitting comprising transmitting a message to a user device associated with an electrical outlet, by the computing device.

11. An apparatus comprising:
a processor;
a non-transitory computer-readable storage medium coupled with the processor; and
a plurality of instructions stored in the storage medium, and configured to enable the apparatus, in response to execution of the instructions by the processor, to:
collect data describing present generating source or sources for one or more present supplies of electricity to an electrical grid;
analyze the data to determine an amount of a present electricity flow on the electrical grid being generated from renewable sources; and
generate and transmit a signal or a message to one or more devices associated with consumption or storage of electricity off the electrical grid, based at least in part on the result of said analysis and determination.

12. The apparatus of claim 11, wherein the instructions are configured to enable the apparatus, in response to execution of the instructions by the apparatus, to collect from one or more electricity generating entities presently generating and supplying electricity to the electrical grid.

13. The apparatus of claim 11, wherein the instructions are configured to enable the apparatus, in response to execution of the instructions by the apparatus, to aggregate the collected data, and to determine a percentage of the present electricity flow on the electrical grid being generated from renewable sources.

14. The apparatus of claim 13, wherein the instructions are configured to enable the apparatus, in response to execution of the instructions by the apparatus, to generate and transmit a signal or a message, in response to said determine, to convey the percentage to the one or more devices.

15. The apparatus of claim 11, wherein the instructions are configured to enable the apparatus, in response to execution of the instructions by the apparatus, to determine, as part of said analyze, whether the amount of the present electricity flow on the electrical grid being generated from one or more renewable sources is less than a current electricity consumption load above a base line level of generation of the electrical grid.

16. The apparatus of claim 15, wherein the instructions are configured to enable the apparatus, in response to execution of the instructions by the apparatus, to generate and transmit a signal or a message, in response to determining that the amount of the present electricity flow on the electrical grid being generated from one or more renewable sources is less than a current electricity consumption load above a base line level of generation of the electrical grid by a predetermined amount.

17. The apparatus of claim 11, wherein the instructions are configured to enable the apparatus, in response to execution of the instructions by the apparatus, to forecast, whether the amount of the present electricity flow on the electrical grid being generated from one or more renewable sources, in an upcoming time period, will be greater than an expected electricity consumption load above a base line level of generation of the electrical grid.

18. The apparatus of claim 17, wherein the instructions are configured to enable the apparatus, in response to execution of the instructions by the apparatus, to generate and transmit a signal or a message, in response to determining that the amount of the present electricity flow on the electrical grid being generated from one or more renewable sources, in an upcoming time period, will be greater than a current electricity consumption load above a base line level of generation of the electrical grid.

19. An article of manufacture, comprising:
a non-transitory computer-readable storage medium; and
a plurality of instructions stored in the storage medium, and configured to enable an apparatus, in response to execution by the processor, to perform operations including:
collecting data describing present generating source or sources for one or more present supplies of electricity to an electrical grid;
analyzing the data to determine an amount of a present electricity flow on the electrical grid being generated from renewable sources; and
generating and transmitting a signal or a message to one or more devices associated with consumption or storage of electricity off the electrical grid, based at least in part on the result of said analysis and determination.

20. The article of claim 19, wherein collecting comprises collecting from one or more electricity generating entities presently generating and supplying electricity to the electrical grid.

21. The article of claim 19, wherein analyzing comprises aggregating the collected data to determine a percentage of the present electricity flow on the electrical grid being generated from renewable sources.

22. The article of claim 19, wherein analyzing comprises determining whether the amount of the present electricity flow on the electrical grid being generated from one or more renewable sources is less than a current electricity consumption load above a base line level of generation of the electrical grid.

23. The article of claim 19, wherein analyzing comprises forecasting, whether the amount of the present electricity flow on the electrical grid being generated from one or more renewable sources, in an upcoming time period, will be greater than an expected electricity consumption load above a base line level of generation of the electrical grid.
